(19) United States
(12) Patent Application Publication
(10) Pub. No.: US 2014/0184242 A1
(43) Pub. Date: Jul. 3, 2014

(54) In-Line Transistor Bandwidth Measurement

(71) Applicant: INTERNATIONAL BUSINESS MACHINES CORPORATION, Armonk, NY (US)

(72) Inventors: Erik L. Hedberg, Essex Junction, VT (US); Daeik D. Kim, West Lafayette, IN (US); Dallas M. Lea, Poughkeepsie, NY (US); Akil K. Sutton, Fishkill, NY (US); Steven J. Zier, Hopewell Junction, NY (US)

(73) Assignee: International Business Machines Corporation, Armonk, NY (US)

(21) Appl. No.: 13/732,474

(22) Filed: Jan. 2, 2013

(51) Int. Cl. G01R 31/26

(52) U.S. Cl. CPC G01R 31/2621
USPC 324/615

(57) ABSTRACT

A method and apparatus measure transistor bandwidth of a device under test in-line and on-wafer. The method includes disposing a measurement circuit on a chip within a wafer, the measurement circuit including a ring oscillator generating an oscillation frequency for transition through the device under test on the wafer, and obtaining an amplitude gain based on the measurement circuit for the corresponding frequency.

### BACKGROUND

The present invention relates to switching circuits, and more specifically, to in-line measurement of the transistor bandwidth.

Performance targeting for complementary metal-oxide-semiconductor (CMOS) silicon-on-insulator (SOI) and bulk technologies is currently facilitated through a logic performance benchmarking methodology that assesses the impact of process elements and step-up plans on inverter delay. The inverter delay is determined by measuring the oscillation frequency of a ring oscillator circuit typically composed of 100 CMOS inverter stages. This approach facilitates the rapid in-line measurement (i.e., measurement during fabrication) of inverter delay used to guide the design of experiments and to obtain data of statistical significance, thereby allowing for decisions that drive the technology performance (measured as inverter delay) to a desired target. Any process element or structural change in the device is presumed to impact the effective resistance or capacitance of components of the measured inverter delay. It is desirable to optimize both delay components to realize the targeted technology performance.

While such an approach is well-suited to logic technology development, there are enough distinctions for high-speed analog and radio frequency (RF) designs such that a logic step-up plan can be neutral or even detrimental to the performance of analog transistors as well as logic transistors intended for use in analog applications. Distinctions in the transistor architecture may be exemplified by the fact that many analog transistors are designed at gate lengths and contacted poly-silicon pitches (CPP) that are necessarily larger than those of logic transistors. Such differences can translate into varying responses to commonly applied performance elements such as nitride stress liners. From a circuit design perspective, the transistors used in analog applications routinely operate in a regime where the drain-to-source voltage (V_{DS}) is compressed to between one half to one third of the supply voltage (V_{DD}). Thus, benchmarking circuits are needed that specifically address the needs of analog designers.

### SUMMARY

According to one embodiment of the invention, a method of measuring transistor bandwidth of a device under test in-line and on-wafer includes disposing a measurement circuit on a chip within a wafer, the measurement circuit including a ring oscillator generating an oscillation frequency for transition through the device under test on the wafer; and obtaining an amplitude based on the measurement circuit for the corresponding oscillation frequency.

According to another embodiment of the invention, a method of measuring transistor bandwidth of a device under test in-line and on-wafer includes applying digital inputs to a decoder to enable corresponding select lines; driving a ring oscillator with the select lines to generate a corresponding frequency output; and obtaining amplitude from the device under test based on the frequency output.

According to yet another embodiment of the invention, an apparatus to measure transistor bandwidth of a device under test in-line and on-wafer includes a decoder including digital input lines and output select lines disposed on a chip within a wafer that includes the device under test; a ring oscillator configured to be driven by the select lines and to generate a frequency output; and a peak and valley detector configured to receive an output from the device under test based on the frequency output of the ring oscillator and to measure amplitude as a peak-to-valley value.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a block diagram of a bandwidth measurement circuit according to an embodiment of the invention;

FIG. 2 illustrates exemplary frequency outputs from the ring oscillator shown in FIG. 1 according to embodiments of the invention;

FIG. 3 illustrates additional exemplary frequency outputs from the ring oscillator shown in FIG. 1 according to embodiments of the invention;

FIG. 4 illustrates the waveforms for the ring oscillator output at two different frequencies with the output waveforms from the CML chain at the corresponding frequencies;

FIG. 5 illustrates an exemplary amplitude (gain) vs. bandwidth plot obtained by using the bandwidth measurement circuit shown in FIG. 1;

FIG. 6 is a block diagram of an exemplary wafer according to embodiments of the invention; and

FIG. 7 is a flow diagram illustrating an exemplary method of measuring bandwidth according to an embodiment of the invention; and

FIG. 8 is a block diagram of an exemplary controller used to process signal output obtained from the bandwidth measurement circuit shown in FIG. 1.

### DETAILED DESCRIPTION

As noted above, logic performance benchmarking by assessing the impact of process elements and step-up plans on inverter delay is not well suited for high-speed analog and RF designs. This issue may be addressed through the on-wafer implementation of ring oscillators sharing a similar architecture as many analog designs and by using analog specific transistors in those ring oscillators. An example of such architecture is current-mode logic (CML). Although a CML chain is specifically discussed herein for purposes of explanation and clarity, the embodiments of the invention described herein are not limited to a CML chain. In alternate embodiments, any switching circuit may be considered as the device under test (DUT). In a CML stage, there are three or more stacks of devices that each operate within a voltage range that is significantly less than the supply voltage. As a result, through the concatenation of these stages into a ring, a delay metric analogous to the inverter delay may be obtained via a rapid in-line measurement.

However, a characteristic of greater interest to product designers than inverter delay is the self-gain of a transistor at a specific frequency—the bandwidth. Despite a small inverter delay, which is favorable, circuit performance may be compromised when there is insufficient signal amplitude. A delay metric lacks information about amplitude, which is lost in the CML to CMOS conversion process. The amplitude can be obtained through the addition of peak and valley detectors on the output of the CML ring oscillator prior to CMOS conversion. However, the detectors would only provide amplitude at a particular frequency but not over a range of frequencies as desired. Currently, one way that this information gap is addressed is through rigorous off-line measurement and tracking of transistor parameters known to influence bandwidth. Specifically, the maximum oscillation frequency, peak cutoff frequency, and trans-conductance are measured and tracked. This approach cannot provide the volume of data required to help guide process decisions and, therefore, is often relegated to use during the model development cycle to assure a strong correlation between the simulated model performance and data obtained from hardware measurement.

Embodiments of the invention described herein use the CML stage to measure the transistor gain (CML signal amplitude) as a function of frequency in an in-line fashion. As detailed below, CML signals of increasing frequency are provided to a chain of CML stages and the amplitude of a stage within the chain is measured. As the frequency of the signal into the chain increases, the amplitude that each CML stage can support is reduced in a manner determined by the bandwidth of the switching transistor. Because the method is in-line, a large volume of statistically relevant data may be collected. In addition, a Bode plot may be interpolated from the measured data to provide information regarding the low-frequency or dc-gain, −3 dB frequency, and 0 dB frequency. In addition, correlation between the measured bandwidth circuit figures-of-merit and transistor parameters may be extracted. When versions of the bandwidth measurement circuit are incorporated into the kerf region of a chip or embedded within product IP, the metrics may be correlated to product IP performance on a chip-by-chip basis.

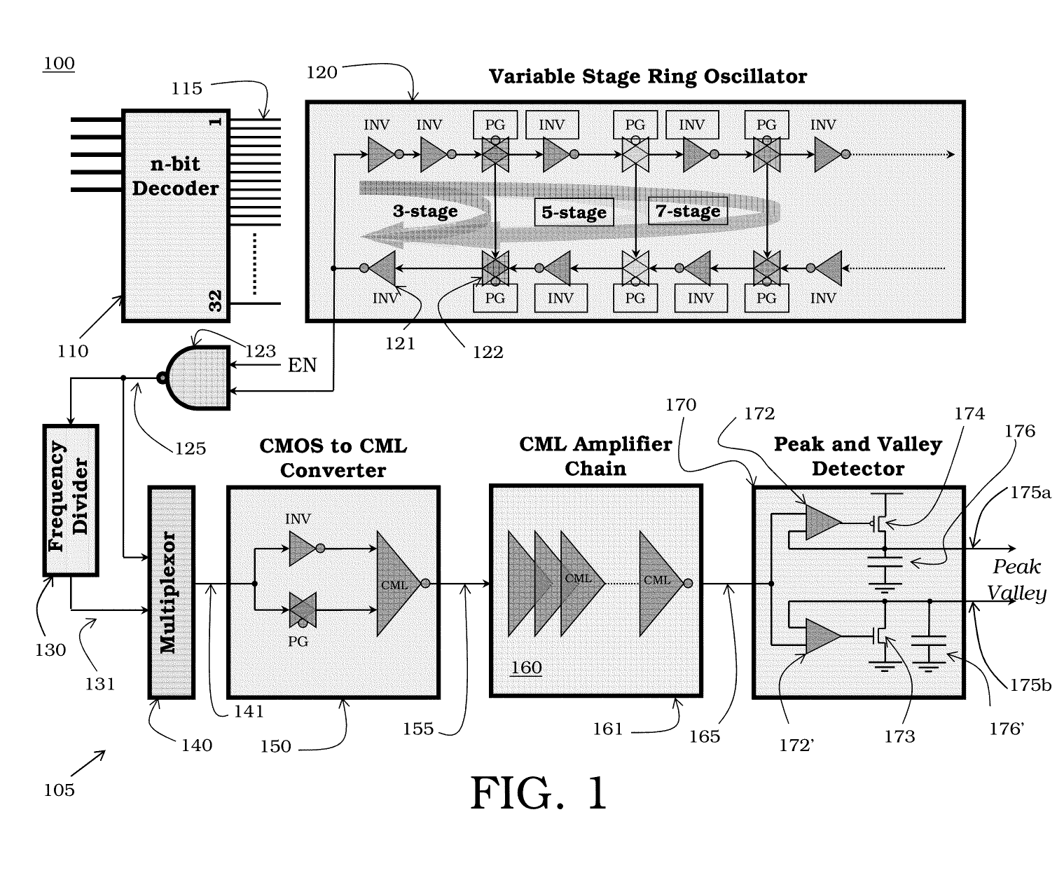

FIG. 1 is a block diagram of a bandwidth measurement circuit 100 according to an embodiment of the invention. In various embodiments of the invention, the bandwidth measurement circuit 100 may be placed in the kerf area of a chip on the wafer 105. The bandwidth measurement circuit 100 includes a decoder 110, a ring oscillator 120 with NAND gate enablement 123, a frequency divider 130, a multiplexor 140, a CMOS to CML converter 150, a device under test (DUT) 161 (a CML amplifier chain 160 in the exemplary embodiment detailed herein), and a peak and valley detector 170. As noted above, the CML chain 160 is discussed as a specific example of a DUT 161 for purposes of explanation, but the DUT 161 may be any switching circuit. The bandwidth measurement circuit 100 on the wafer 105, not only facilitates in-line testing but also facilitates testing after multiple processing steps to track performance. The components of the bandwidth measurement circuit 100 are detailed below.

The decoder 110 and ring oscillator 120 together comprise the frequency generation portion of the bandwidth measurement circuit 100. The decoder 110 includes a series of select lines 115 that are inputs to the ring oscillator 120. Digital inputs are asserted to the decoder 110 to enable the select lines 115. The ring oscillator 120, which is a variable stage ring oscillator in the embodiment shown by FIG. 1, comprises modular banks of bidirectional CMOS static inverter chains (INV 121) that include dual pass gates (PG 122). The select lines 115 are fed to the dual pass gates 122 that are spread throughout the ring oscillator 120. When a given select line 115 goes high, the corresponding dual pass gate 122 sends the incoming ring signal back out through the inverter chain 121 in the outgoing (lower in FIG. 1) direction of the bank. When a given select line 115 goes low, the corresponding dual pass gate 122 feeds the incoming ring signal through to the next bank of chained inverters 121 oriented in the same direction through the incoming (upper in FIG. 1) portion of the bank. Therefore, by individually controlling the select lines 115, the number of inverter stages within the ring oscillator can be controlled. Because the frequency of the observed oscillation is inversely proportional to the number of inverter stages in the ring, controlling the select lines 115 facilitates controlling the frequency produced at the output of the ring oscillator 120. Specifically, the 5-bit decoder 110, as in the exemplary embodiment shown in FIG. 1, can produce up to thirty two unique oscillation frequencies on the wafer 105. In alternate embodiments, another decoder 110 of a different capacity may be used.

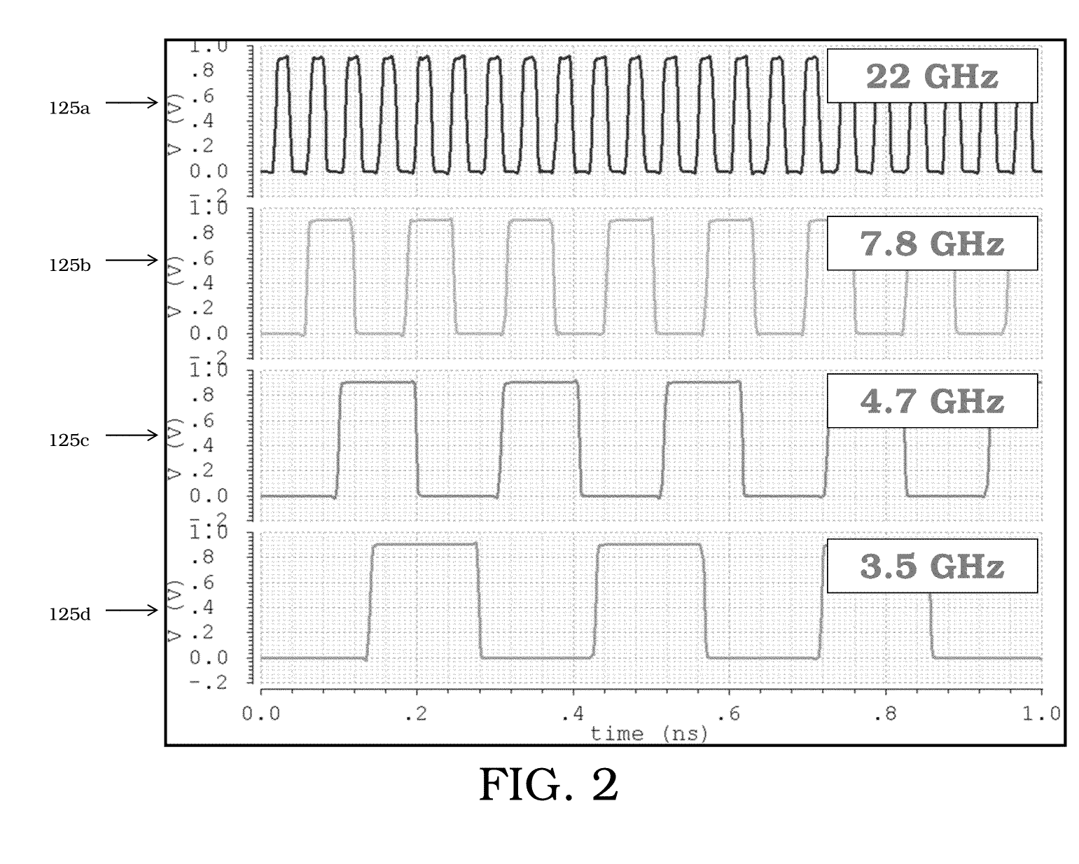

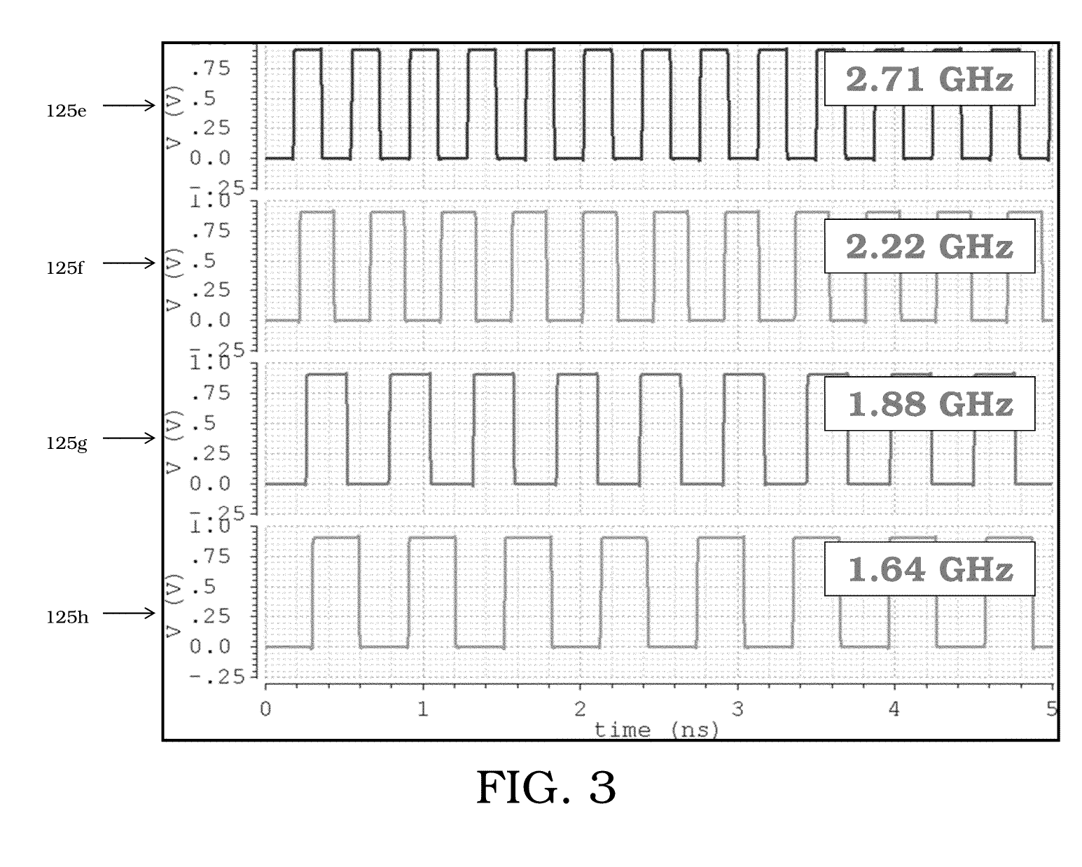

FIG. 2 illustrates exemplary frequency outputs 125a-125d from the ring oscillator 120 shown in FIG. 1 according to embodiments of the invention. The exemplary frequency outputs 125a-125d are in the GHz range and the decreasing frequency from 125a to 125d corresponds to an increasing number of inverter stages in the ring oscillator 120 (i.e., increasing number of low select lines 115). That is, frequency outputs 125a-125d correspond to the “fast” frequencies of the ring oscillator 120. They represent the case when inputs of the exemplary 5-bit decoder 110 of FIG. 1 are on the low end of the ‘1’ to ‘32’ scale. For example, frequency output 125a at 22 GHz represents select line 115 ‘1’ being high, which corresponds to a 3-stage ring, and frequency output 125b at 7.8 GHz represents select line 115 ‘3’ being high, which corresponds to a 7-stage ring. The number of stages in the ring is a prime number to prevent aliasing. In this high-frequency regime of operation, the frequency output 125 is not divided before going through the CML chain 160. FIG. 3 illustrates additional exemplary frequency outputs 125e-125h from the ring oscillator 120 shown in FIG. 1 according to embodiments of the invention. The frequency outputs 125e-125h are nearing the MHz range to capture the low-frequency portion of the Bode plot. They represent the sampling of select lines 115 around ‘18’ to ‘24’ which correspond to a higher number of inverter stages in the ring. These frequency outputs 125 may be further divided (to the kHz range) using the frequency divider 130. By implementing a multiplexor 140, either the high-frequency 125 or low-frequency 131 outputs of the ring oscillator 120 may be supplied to the CMOS to CML converter 150 and the CML amplifier chain 160.

Once the ring frequency of interest (ring oscillator signal 125 or 131) is output (141) from the multiplexor 140, it may be converted from a full CMOS swing (0 to power supply voltage, V_{DD}) to a partial CML swing by the CMOS-CML converter 150, as is typically done in analog product designs. The output of the CMOS-CML converter (155) then transitions through CML stages of the CML chain 160 until it is output (165) to the peak and valley detector 170. The peak and valley detector 170 includes a full rail differential buffer 172 whose output is tied to the gate of a long-channel p-type field effect transistor (PFET) 174. The source of the PFET 174 is tied to V_{DD} and the drain of the PFET 174 is connected to ground through a capacitor 176. The drain of the PFET 174 is also tied to the peak output node 175a and to the non-inverting input of the buffer 172 while the signal 165 is fed to the inverting input of the buffer 172. Once the non-inverting input is greater than the inverting input (165), the output signal from the buffer 172 to the gate of the PFET 174 is high. This ensures that the PFET 174 stays off and the peak voltage (at 175a) is read as the voltage stored in the capacitor 176. If the inverting input (the signal 175) rises past the non-inverting input, the output of the buffer 172 will begin to fall, turning the PFET 174 on and allowing charge to flow from the supply into the capacitor 176, thereby increasing the peak output node 175a. At the same time, the voltage on the non-inverting input increases, thereby eventually sending the buffer 172 output back high and turning the PFET 174 off. The determination of the valley of the swing (at 175b) is analogous to determining the peak (at 175a), except that the valley gets lower because the gate on a n-type FET (NFET) 173 connected from the valley output (175b) to ground is turned on when the inverting input of the differential buffer 172′ falls below that of the non-inverting input. The charge is stored in a capacitor 176′ connected across the terminals of the NFET 173 (across the valley output (175b) to ground). The amplitude of the CML signal can then be calculated as the peak-to-valley (peak-valley) value.

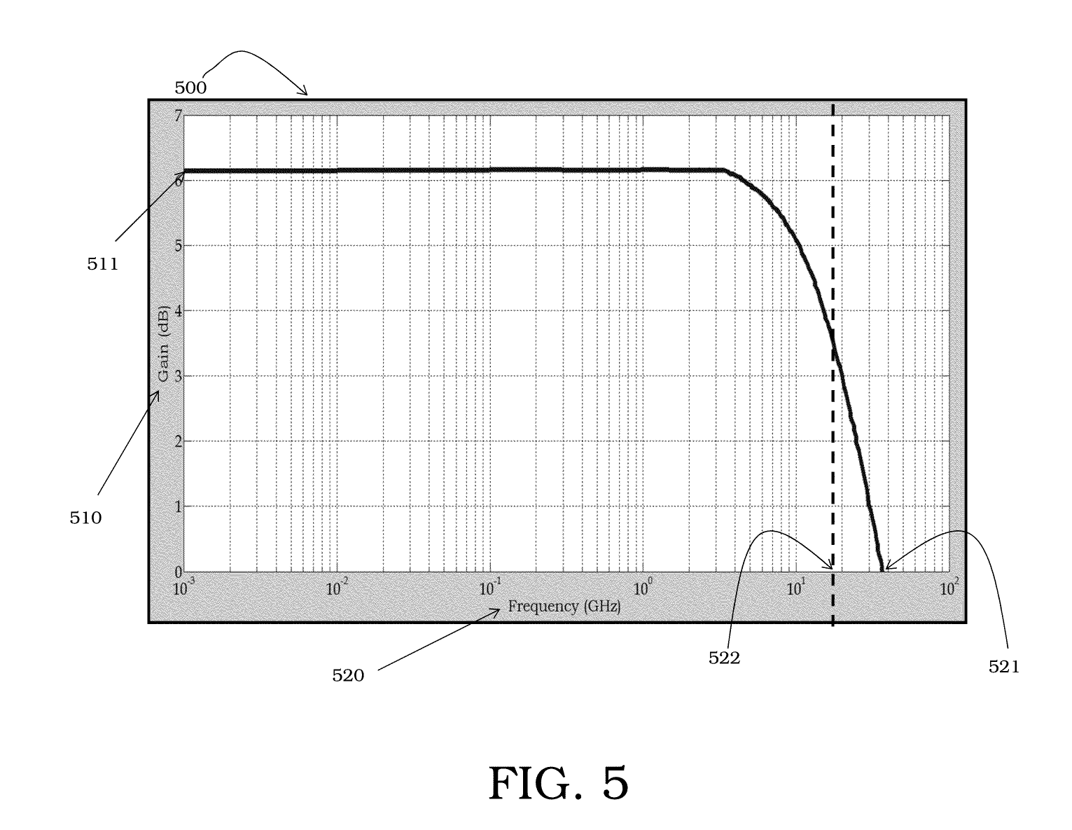

In one or more embodiments, the inverter stages of the ring oscillator 120 may be unloaded for faster oscillation or loaded by a metal oxide semiconductor capacitor (MOSCAP) to reduce the oscillation frequency. For example, at the 22 nm silicon-on-insulator (SOI) technology node, a three-stage unloaded ring may demonstrate a 47 GHz oscillation frequency while a 457-stage MOSCAP loaded ring may provide a 225 MHz oscillation frequency. In order to replicate the Bode plot (as in FIG. 5), which represents gain as a function of frequency, several orders of magnitude of variation in the CMOS ring frequency that will be fed into the CML chain 160 are needed. This may be achieved by enabling a static divider (130), similar to what is used to down-convert frequencies for in-line measurement prior to feeding into the CML chain 140.

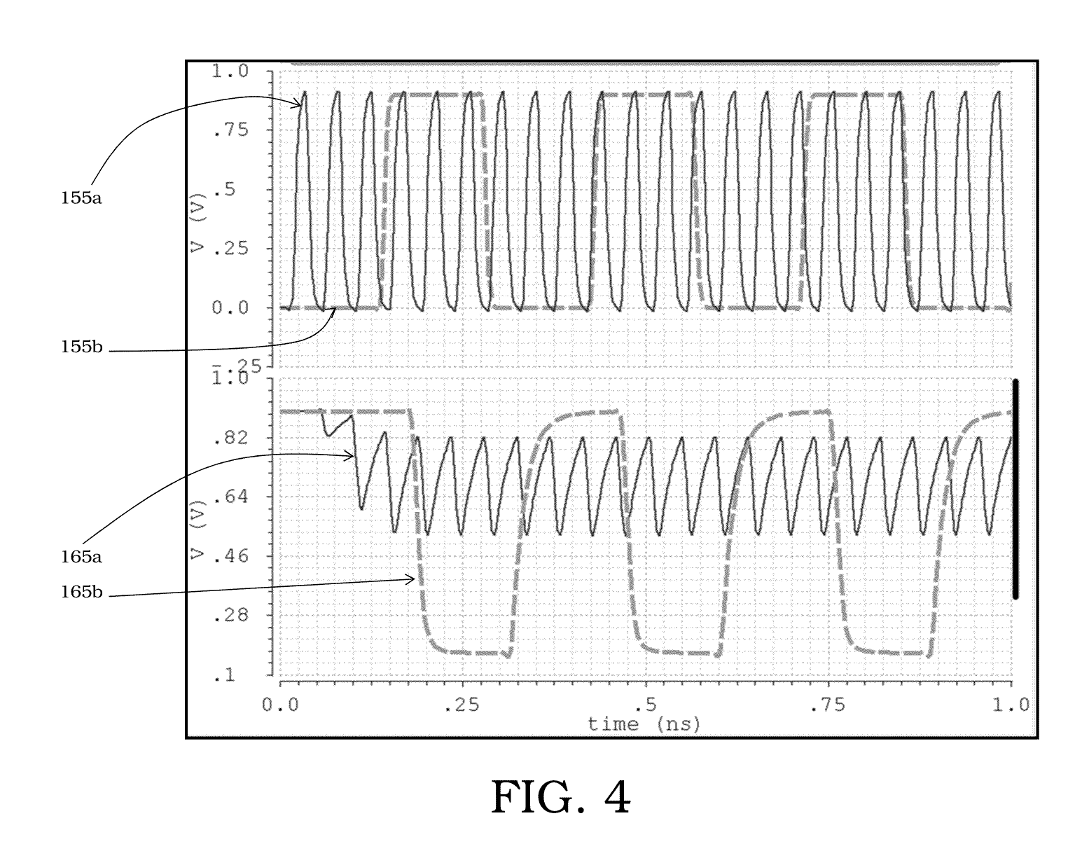

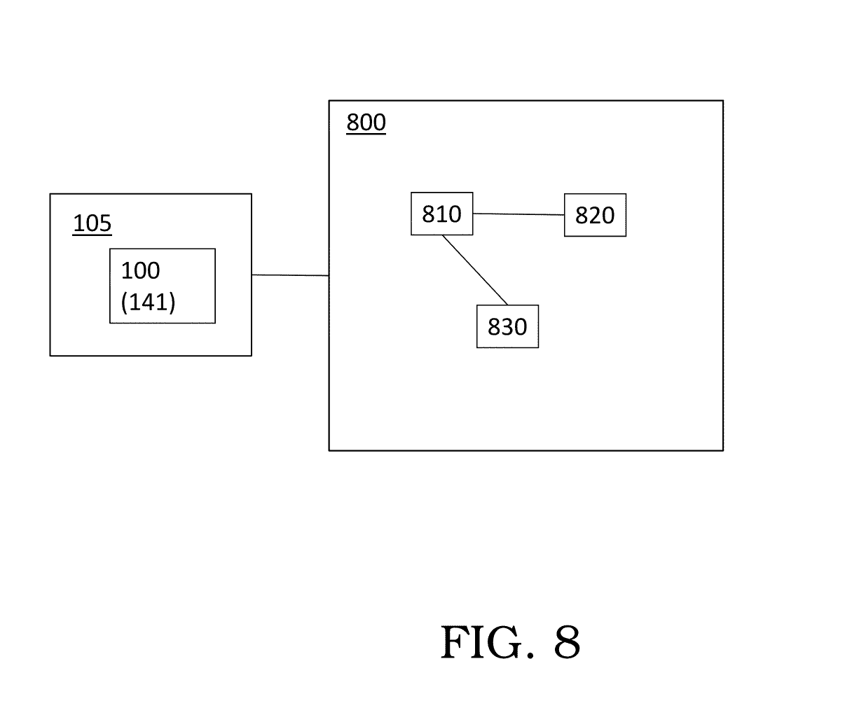

FIG. 4 illustrates the waveforms for the ring oscillator 120 output at two different frequencies with the output waveforms (165a and 165b) from the CML chain 160 at the corresponding frequencies. The two different ring oscillator 120 output frequencies 155a, 155b shown in FIG. 4 are 22 GHz and 3.5 GHz, respectively. As the frequency of the ring oscillator 120 signal (155) being fed into the CML chain 160 increases, the amplitude is reduced because FETs within the CML chain 160 are unable to switch at the same speed as the signal 155. The amplitude gain and frequency, for example, the down-converted frequency, may be stored and/or displayed by one or more processors 810, one or more memory devices 820, and a display device 830 (discussed with reference to FIG. 8) internal or external to the wafer 105.

FIG. 5 illustrates an exemplary bandwidth plot 500 obtained by using the bandwidth measurement circuit 100. The exemplary bandwidth plot 500 illustrates the gain or CML amplitude (plotted on the y-axis 510) decrease when the frequency (plotted on the x-axis 520) increases. Performance metrics such as the low-frequency gain 511, −3 dB frequency 522, and unity frequency 521 are highlighted. In one embodiment, the devices used to generate the CMOS signal 125 are standard logic FETs and are typically of a shorter channel length than the smallest analog specific FET. In addition, in the CML implementation, the analog FET operates under a compressed drain-to-source voltage. Because of these two factors, the frequency of the CMOS ring oscillation becomes too fast at some point for the analog-specific FET used in the CML switching. As a result, as shown in FIG. 4, the amplitude decreases as the gate voltage switches before the drain can reach the voltage level determined by the previous value of the gate voltage.

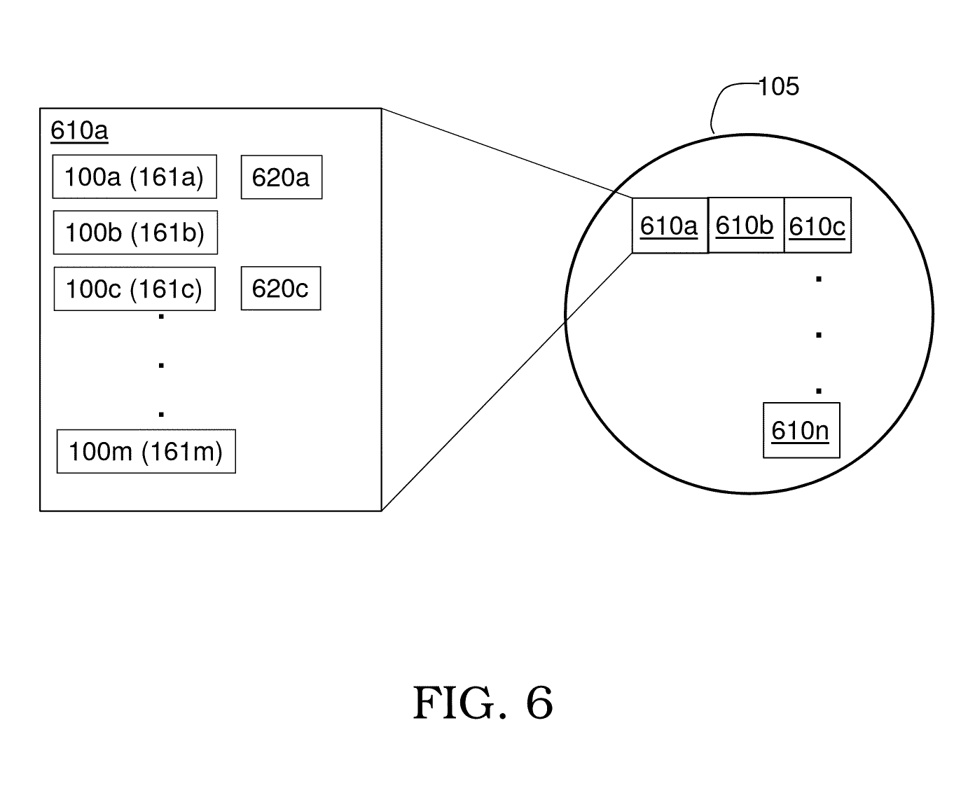

In one embodiment, on a 1×25 set of pads, a bandwidth measurement circuit (circuit 100) may be created with a decoder 110 (5 pads), a ring oscillator 120 (3 pads), 6 sets of CML chains 160 featuring different transistor types within (12 pads), peak and valley outputs 175a, 175b (2 pads), frequency 141, common V_{DD}, and substrate taps. The bandwidth measurement circuits according to the present embodiment may be placed in the kerf areas of the wafer 105. In an alternate embodiment, the macro (circuit 100) may be embedded in the actual product IP as discussed with reference to FIG. 6. In this case, the pad count may be minimized and, as such, an additional decoder 110 may be added to enable selection among different types of DUTs 161. The peak and valley outputs 175a, 175b from each DUT 161 may be multiplexed. All digital inputs to the decoder 110 may be serially loaded via shift registers. In this case, at the end, only four unique pins (digital input, peak, valley, and frequency) would be needed if the power and ground are shared among the different circuit components on the chip.

FIG. 6 is a block diagram of an exemplary wafer 105 according to embodiments of the invention. The wafer 105 includes a number of chips 610. Each chip 610 may include one or more bandwidth measurement circuits 100 and corresponding DUTs 161. Each chip 610 may also include product IP circuits 620. When the DUT 161 includes a device of interest that is also located in a product circuit 620, the bandwidth measurement circuit 100 can be used to sort and disposition the products based upon using the transistor bandwidth (determined by the bandwidth measurement circuit 100) as a measure of speed. For example, for the exemplary wafer 105 shown in FIG. 5, the product circuit 620c includes a device (a performance determinative device, for example) that is also included in the DUT 161c. In this case, the bandwidth determined by the bandwidth measurement circuit 100c would provide a measure of speed for the product including the product circuit 620c. When this is done for various product circuits 620 on the wafer 105, performance benchmarking or sorting (of product circuits 620 based on speed) can be done. That is, for example, a product circuit 620 found to be the fastest among those on the wafer 105 may be identified for use in an application requiring that speed while product circuits 620 found to be slower than needed would not be used.

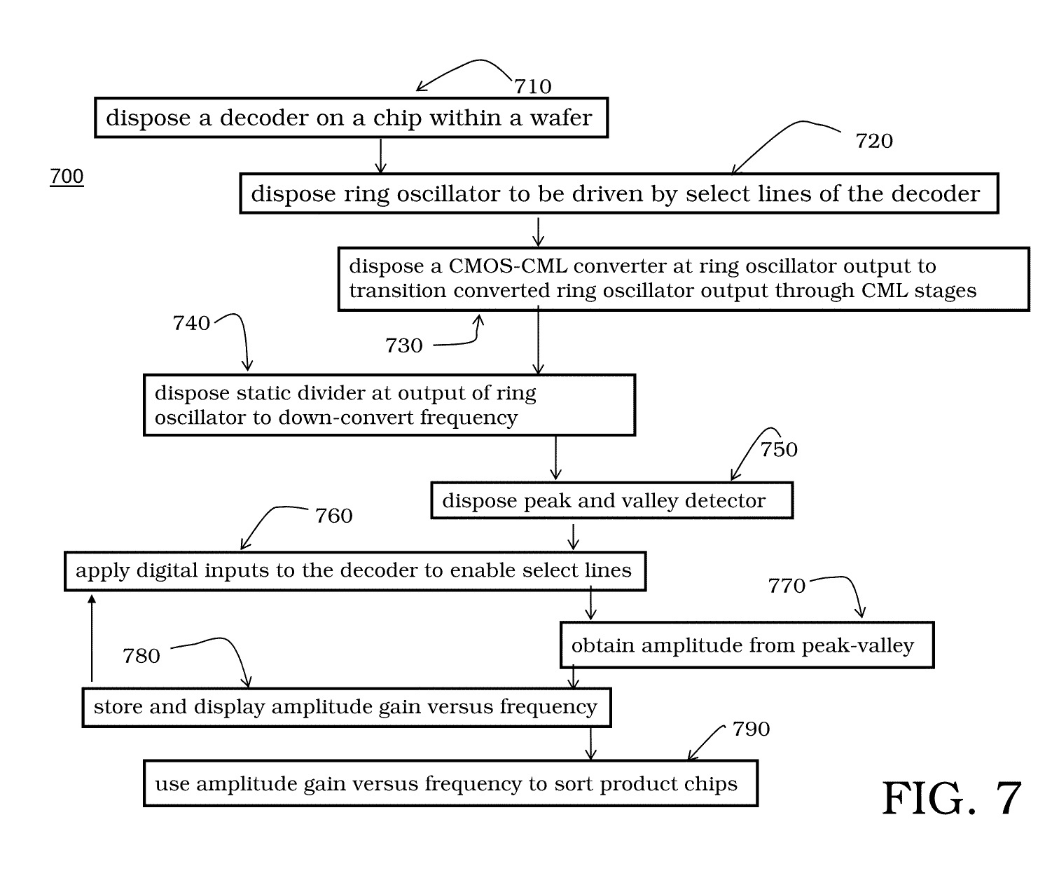

FIG. 7 is a flow diagram illustrating an exemplary method 700 of measuring bandwidth according to an embodiment of the invention. At block 710, the method 700 includes disposing a decoder 110 on the wafer 105 including the DUT 161 (CML chain 160 in the exemplary embodiment). At block 720, disposing a ring oscillator 120 to be driven by select lines 115 of the decoder 110 may include disposing a variable stage ring oscillator 120 as shown in FIG. 1. At block 730, the method 700 includes disposing a CMOS-CML converter 150 at the ring oscillator 120 output 125 to transition the converted ring oscillator output 141 through the CML stages of the CML chain 160. The method 700 includes disposing a static divider 130 at the output of the ring oscillator 120 to down-convert the frequency at block 740, and disposing a peak and valley detector 170 at block 750. At block 760, applying digital inputs to the decoder 110 to enable select lines 115 allows selection of the frequency generated by the ring oscillator 120. At block 770, obtaining amplitude from the peak 175a to valley 175b value is at the output of the peak and valley detector 170. Based on that amplitude and the input frequency (input from the ring oscillator 120), the method 700 includes storing and displaying amplitude gain versus frequency at block 780. At block 790, the method 700 may include using the gain (amplitude) versus frequency to sort product chips as discussed with reference to FIG. 6 above.

FIG. 8 is a block diagram of an exemplary controller 800 used to process bandwidth information obtained from the bandwidth measurement circuit 100 shown in FIG. 1. As noted above, one or more of the processors 810 may work in conjunction with the one or more memory devices 820 to store bandwidth information obtained from the bandwidth measurement circuit 100 for a DUT 161 (such as the CML chain 160 discussed above). The processor 810 may also display the bandwidth information, for example, as a Bode plot, using the display device 830. As also noted above, the controller 800 may be part of the bandwidth measurement circuit 100 or, alternatively, may be external to the bandwidth measurement circuit 100 and additionally to the wafer 105, as shown in FIG. 8.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagram depicted herein is just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method of measuring transistor bandwidth of a device under test in-line and on-wafer, the method comprising:
disposing a measurement circuit on a chip within a wafer, the measurement circuit including a ring oscillator generating an oscillation frequency for transition through the device under test on the wafer; and
obtaining an amplitude based on the measurement circuit for the corresponding oscillation frequency.

2. The method according to claim 1, wherein the device under test is a switching circuit.

3. The method according to claim 1, wherein the device under test is a current mode logic (CML) chain.

4. The method according to claim 1, wherein the disposing the measurement circuit is in the kerf area of the wafer.

5. The method according to claim 1, wherein the disposing the measurement circuit includes disposing a decoder, the ring oscillator, a converter, and a peak and valley detector.

6. The method according to claim 3, further comprising applying digital inputs to the decoder to enable select lines driving the ring oscillator to generate the oscillation frequency

7. The method according to claim 3, further comprising obtaining the amplitude based on an output of the device under test to the peak and valley detector.

8. The method according to claim 1, wherein the disposing the measurement circuit further includes disposing a static divider to divide the oscillation frequency generated by the ring oscillator and provide a down-converted frequency.

9. The method according to claim 8, further comprising the measurement circuit outputting the amplitude and the down-converted frequency for display or storage.

10. The method according to claim 9, further comprising disposing a controller including a processor to process the amplitude and corresponding down-converted frequency.

11. The method according to claim 1, further comprising performance benchmarking a product design including a device corresponding with the device under test based on the bandwidth.

12. A method of measuring transistor bandwidth of a device under test in-line and on-wafer, the method comprising:
applying digital inputs to a decoder to enable corresponding select lines;
driving a ring oscillator with the select lines to generate a corresponding frequency output; and
obtaining amplitude from the device under test based on the frequency output.

13. The method according to claim 12, further comprising storing the amplitude and corresponding frequency for a set of frequency output.

14. The method according to claim 13, wherein generating the set of frequency output includes applying different respective digital inputs to the decoder.

15. The method according to claim 12, further comprising performance benchmarking a product design including a device corresponding with the device under test based on the bandwidth.

16. An apparatus to measure transistor bandwidth of a device under test in-line and on-wafer, the apparatus comprising:
a decoder including digital input lines and output select lines disposed on a chip within a wafer that includes the device under test;
a ring oscillator configured to be driven by the select lines and to generate a frequency output; and
a peak and valley detector configured to receive an output from the device under test based on the frequency output of the ring oscillator and to measure amplitude as a peak-to-valley value.

17. The apparatus according to claim 16, wherein the device under test is a switching circuit.

18. The apparatus according to claim 16, wherein the device under test is a current mode logic (CML) chain.

19. The apparatus according to claim 16, further comprising a static divider to down-convert the frequency output and output a down-converted frequency output.

20. The apparatus according to claim 19, further comprising a controller including a processor, memory device, and display device, the controller configured to store or display the amplitude and corresponding down-converted frequency output.
